(19) United States
(12) Patent Application Publication
(10) Pub. No.: US 2006/0148211 A1
(43) Pub. Date: Jul. 6, 2006

(54) Wafer dividing method

(75) Inventors: Kenichi Iwasaki, Tokyo (JP); Satoshi Genda, Tokyo (JP); Toshio Tsuchiya, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/324,323

(22) Filed: Jan. 4, 2006

(30) Foreign Application Priority Data
Jan. 5, 2005 (JP) 2005-000823

(51) Int. Cl. H01L 21/78

(52) U.S. Cl. 438/462; 438/463

(57) ABSTRACT

A wafer dividing method for cutting a wafer having devices which are composed of a laminate laminated on the front surface of a substrate with a cutting blade along a plurality of streets for sectioning the devices, comprising the steps of a groove forming step for forming two grooves deeper than the thickness of the laminate at an interval larger than the thickness of the cutting blade by applying a laser beam along the streets formed on the wafer; an alignment step for picking up an image of the two grooves formed in the streets of the wafer by the above groove forming step and positioning the cutting blade at the center position between the two grooves based on the image; and a cutting step for moving the cutting blade and the wafer relative to each other while the cutting blade is rotated to cut the wafer along the streets having the two grooves formed therein, after the above alignment step.

### FIELD OF THE INVENTION

The present invention relates to a method of dividing a wafer along streets formed on the front surface of a wafer such as a semiconductor wafer or the like.

### DESCRIPTION OF THE PRIOR ART

As is known to people of ordinary skill in the art, a semiconductor wafer having a plurality of semiconductor chips such as IC's or LSI's, which are composed of a laminate consisting of an insulating film and a functional film and formed in a matrix on the front surface of a semiconductor substrate such as a silicon substrate or the like, is manufactured in the production process of a semiconductor device. The thus-formed semiconductor chips are sectioned by dividing lines called “streets” in this semiconductor wafer, and individual semiconductor chips are manufactured by dividing the semiconductor wafer along the streets.

Dividing along the streets of the above semiconductor wafer is generally carried out by using a cutting machine called “dicer”. This cutting machine comprises a chuck table for holding a semiconductor wafer as a workpiece, a cutting means for cutting the semiconductor wafer held on the chuck table, and a moving means for moving the chuck table and the cutting means relative to each other. The cutting means comprises a rotary spindle that is rotated at a high speed and a cutting blade mounted on the spindle. The cutting blade comprises a disk-like base and an annular cutting edge, which is mounted on the side wall peripheral portion of the base and formed by fixing diamond abrasive grains having a diameter of about 3 μm to the base by electroforming.

To improve the throughput of a semiconductor chip such as IC or LSI, a semiconductor wafer comprising semiconductor chips which are composed of a laminate consisting of a low-dielectric insulating film (Low-k film) formed of a film of an inorganic material such as SiOF or BSG (SiOB) or a film of an organic material such as a polyimide-based and parylene-based polymer and a functional film for forming circuits on the front surface of a semiconductor substrate such as a silicon substrate or the like has recently been implemented.

Further, a semiconductor wafer having a metal pattern called “test element group (TEG)”, which is constituted to be partially formed on the streets of the semiconductor wafer so as to test the function of each circuit through the metal pattern before it is divided has also been implemented.

Because of a difference in the material of the above Low-k film or test element group.(TEG) from that of the wafer, it is difficult to cut the wafer together with them at the same time with the cutting blade. That is, as a Low-k film is extremely fragile like mica, when the above semiconductor wafer having the Low-k film laminated thereon is cut along the streets with the cutting blade, a problem arises that the Low-k film peels off, and this peeling reaches the circuits, thereby causing a fatal damage to the semiconductor chips. Also, since the test element group (TEG) is made of a metal, a problem may occur that a burr is produced when the semiconductor wafer having the test element group (TEG) is cut with the cutting blade.

To solve the above problems, the applicant of the present application has proposed a wafer dividing method for cutting a semiconductor wafer along the streets, which comprises forming two grooves along the streets formed on the semiconductor wafer to divide the laminate, positioning the cutting blade between the outer sides of the two grooves, and moving the cutting blade and the semiconductor wafer relative to each other as JP-A 2005-64231.

To form grooves in a street formed on the semiconductor wafer by a laser beam processing machine, the street is detected to carry out the alignment work of the area to be processed. However, as there is no feature point on the street, it is difficult to detect the street directly. Therefore, the feature points of the circuits (semiconductor chips) formed on the semiconductor wafer are used as a key pattern, and the positional relationship between the streets and the key pattern is in advance stored in the memory of a control means, and an image of the key pattern is picked up to detect the streets indirectly by a pattern matching method. Meanwhile, to detect a street to be cut, the cutting machine, too, detects the street indirectly by the above pattern matching method as well. Therefore, there is a small error between the detection of a street by the pattern matching of the laser beam processing machine and the detection of a street by the pattern matching of the cutting machine. As a result, when a semiconductor wafer W is to be cut along a street S by the laser beam processing machine as shown in FIG. 14, there is a possibility a cutting blade B may not be positioned at the center position between grooves G and G precisely. Therefore, a problem occurs that the cutting blade B inclines toward a side having smaller cutting resistance and may damage a circuit (semiconductor chip) C.

### SUMMARY OF THE INVENTION

It is an object of the present invention to provide a wafer dividing method capable of cutting the wafer along streets by forming two grooves in both side portions in the transverse direction of each street of the wafer by a laser beam processing machine and by positioning a cutting blade of a cutting machine at the center position between the grooves precisely.

To attain the above object, according to the present invention, there is provided a wafer dividing method for cutting a wafer having devices which are composed of a laminate laminated on the front surface of a substrate, with a cutting blade along a plurality of streets for sectioning the devices, comprising the steps of:

a groove forming step for forming two grooves deeper than the thickness of the laminate at an interval larger than the thickness of the cutting blade by applying a laser beam along the streets formed on the wafer;

an alignment step for picking up an image of the two grooves formed in the streets of the wafer by the above groove forming step and positioning the cutting blade at the center position between the two grooves based on the image; and

a cutting step for moving the cutting blade and the wafer relative to each other while the cutting blade is rotated to cut the wafer along the streets having the two grooves are formed therein, after the above alignment step.

Since the alignment step for picking up an image of the two grooves formed in each street of the wafer by the groove forming step and positioning the cutting blade at the center position between the two grooves based on the image is carried out in the wafer dividing method of the present invention, the wafer can be cut after positioning the cutting blade at the center position between the two grooves precisely in the cutting step. Therefore, the cutting blade in the cutting step is prevented from slanting, thereby making it possible to prevent the damage of the chips by the slanting of the cutting blade.

### BRIEF DESCRIPTION OF THE DRAWINGS

FIG. 1 is a perspective view of a semiconductor wafer to be divided by the wafer dividing method of the present invention:

FIG. 2 is an enlarged sectional view of the semiconductor wafer shown in FIG. 1;

FIG. 3 is a perspective view showing a state where the semiconductor wafer shown in FIG. 1 is supported on an annular frame through a protective tape;

FIG. 4 is a perspective view of the principal portion of a laser beam processing machine for carrying out a groove forming step in the wafer dividing method of the present invention;

FIG. 5 is a block diagram schematically showing the constitution of a laser beam application means provided in the laser beam processing machine shown in FIG. 4;

FIG. 6 is a schematic diagram explaining the focusing spot diameter of a laser beam;

FIGS. 7(a) and 7(b) are explanatory diagrams showing a groove forming step in the wafer dividing method of the present invention;

FIG. 8 is an enlarged sectional view of the principal portion of a semiconductor wafer having grooves formed along a street of the semiconductor wafer by the groove forming step shown in FIGS. 7(a) and 7(b);

FIG. 9 is a perspective view of the principal portion of a cutting machine for carrying out a cutting step in the wafer dividing method of the present invention;

FIG. 10 is an enlarged view of an image picked up by an image pick-up means provided in the cutting machine shown in FIG. 9;

FIGS. 11(a) and 11(b) are explanatory diagrams showing a cutting step in the wafer dividing method of the present invention;

FIG. 12 is an explanatory diagram showing a state wherein the semiconductor wafer has been positioned at the cutting start position in the cutting step shown in FIG. 1.11(a) and 11(b);

FIGS. 13(a) and 13(b) are explanatory diagrams showing a state where the semiconductor wafer is cut along the grooves by the cutting step in the wafer dividing method of the present invention; and

FIG. 14 is an explanatory diagram showing a state where the cutting blade slants in the cutting step in the wafer dividing method of the prior art.

### DETAILED DESCRIPTION OF THE PREFERRED EMBODIMENTS

The wafer dividing method of the present invention will be described in detail hereinunder with reference to the accompanying drawings.

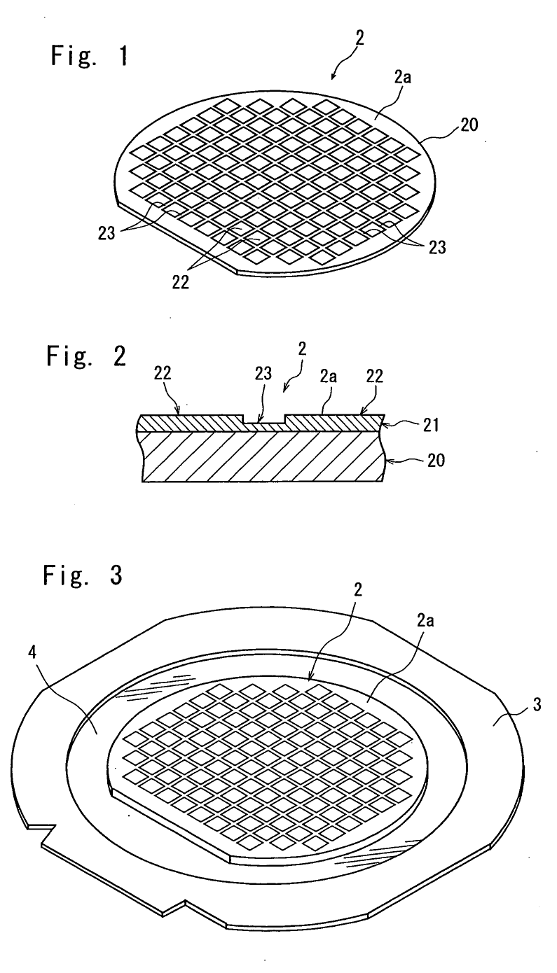

FIG. 1 is a perspective view of a semiconductor wafer to be divided into individual chips by the wafer dividing method of the present invention, and FIG. 2 is an enlarged sectional view of the principal portion of the semiconductor wafer shown in FIG. 1. In the semiconductor wafer 2 shown in FIG. 1 and FIG. 2, a plurality of semiconductor chips 22 (devices) such as IC's or LSI's, which are composed of a laminate 21 consisting of an insulating film and a functional film for forming circuits, are formed in a matrix on the front surface of a semiconductor substrate 20 such as a silicon substrate. The semiconductor chips 22 are sectioned by streets 23 formed in a lattice pattern. In the illustrated embodiment, the insulating film for forming the laminate 21 is an SiO₂ film or a low-dielectric insulating film (Low-k film) formed of a film of an inorganic material such as SiOF or BSG (SiOB) or a film of an organic material such as a polyimide-based and parylene-based polymer.

To divide the above-described semiconductor wafer 2 along the streets 23, the semiconductor wafer 2 is put on a protective tape 4 mounted on an annular frame 3 as shown in FIG. 3. At this point, the semiconductor wafer 2 is put on the back surface of the protective tape 4 in such manner that the front surface 2a faces up.

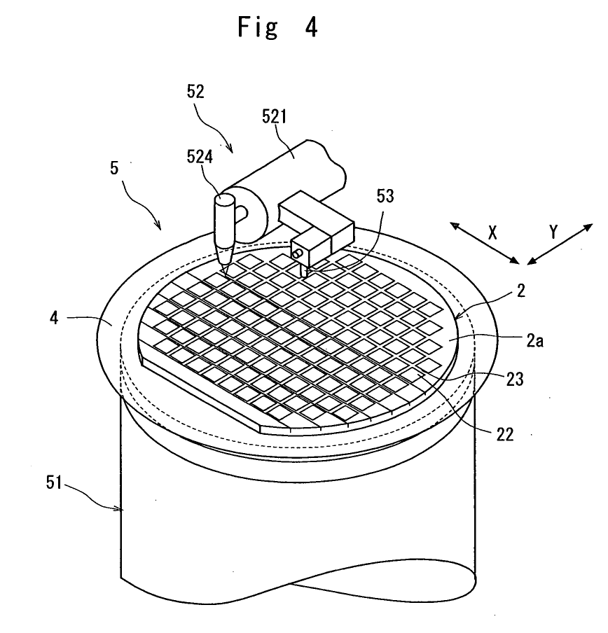

Next comes a groove forming step for forming two grooves deeper than the thickness of the laminate 21 at an interval larger than the thickness of the cutting blade, which will be described later, by applying a laser beam along the streets 23 of the semiconductor wafer 2. This groove forming step is carried out by using a laser beam processing machine 5 shown in FIGS. 4 to 6. The laser beam processing machine 5 shown in FIGS. 4 to 6 comprises a chuck table 51 for holding a workpiece and a laser beam application means 52 for applying a laser beam to the workpiece held on the chuck table 51. The chuck table 51 is constituted so as to suction-hold the workpiece and is designed to be moved in a processing-feed direction indicated by an arrow X in FIG. 4 by a processing-feed mechanism (not shown) and an indexing-feed direction indicated by an arrow Y by an indexing-feed mechanism that is not shown.

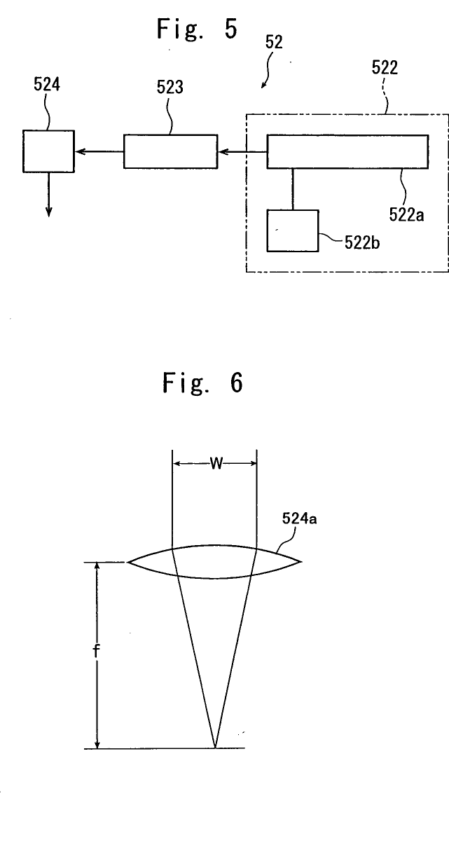

The above laser beam application means 52 has a cylindrical casing 521 arranged substantially horizontally. In the casing 521, as shown in FIG. 5, there are installed a pulse laser beam oscillation means 522 and a transmission optical system 523. The pulse laser beam oscillation means 522 comprises a pulse laser beam oscillator 522a composed of a YAG laser oscillator or YVO4 laser oscillator and a repetition frequency setting means 522b connected to the pulse laser beam oscillator 522a. The transmission optical system 523 comprises suitable optical elements such as a beam splitter, etc. A condenser 524 housing condenser lenses (not shown) constituted by a set of lenses that may be formation known per se is attached to the end of the above casing 521. A laser beam oscillated from the above pulse laser beam oscillation means 522 reaches the condenser 524 through the transmission optical system 523 and is applied to the workpiece held on the above chuck table 51 from the condenser 524 at a predetermined focusing spot diameter D. This focusing spot diameter D is defined by the expression D (μm) =4×λ×f/(π×W) (wherein λ is the wavelength (μm) of the pulse laser beam, W is the diameter (mm) of the pulse laser beam applied to an objective condenser lens 524a, and f is the focusing distance (mm) of the objective condenser lens 524a) when the pulse laser beam showing a Gaussian distribution is applied through the objective condenser lens 524a of the condenser 524 as shown in FIG. 6.

The illustrated laser beam processing machine 5 comprises an image pick-up means 53 attached to the end of the casing 521 constituting the above laser beam application means 52, as shown in FIG. 4. This image pick-up means 53 picks up an image of the workpiece held on the chuck table 51. The image pick-up means 53 is constituted by an optical system and an image pick-up device (CCD), and transmits an image signal to a control means that is not shown.

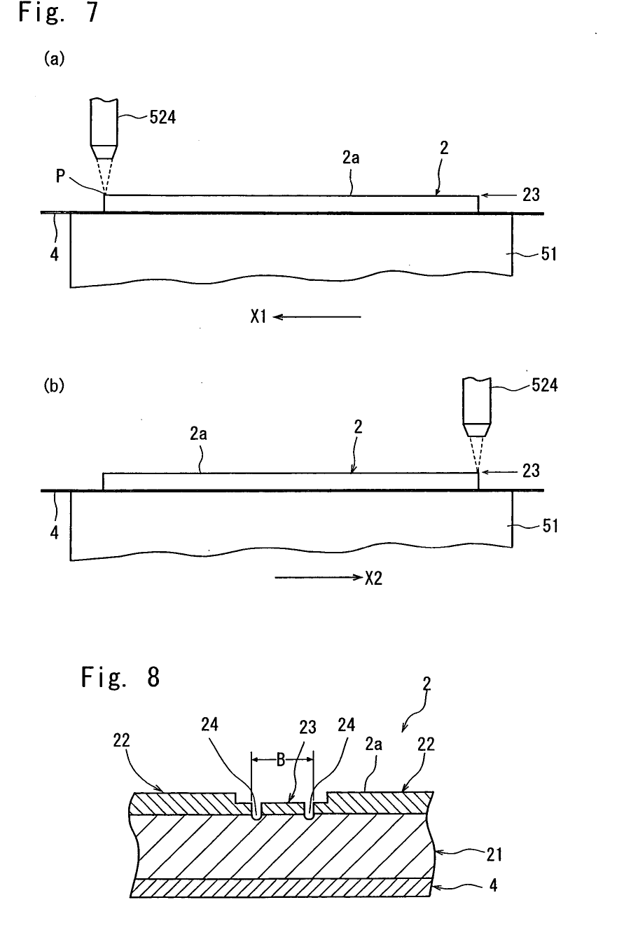

A description will be subsequently given of a groove forming step which is carried out by using the above laser beam processing machine 5 with reference to FIG. 4, FIGS. 7(a) and 7(b) and FIG. 8.

In this groove forming step, the semiconductor wafer 2 is first placed on the chuck table 51 of the laser beam processing machine 5 shown in FIG. 4 and suction-held on the chuck table 51. At this point, the semiconductor wafer 2 is held in such a manner that the front surface 2a faces up. Although the annular frame 3 on which the protective tape 4 is mounted is not shown in FIG. 4, it is held by a suitable frame holding means provided on the chuck table 51.

The chuck table 51 suction-holding the semiconductor wafer 2 as described above is brought to a position right below the image pick-up means 53 by the processing-feed mechanism that is not shown. After the chuck table 51 is positioned right below the image pick-up means 53, alignment work for detecting the area to be processed of the semiconductor wafer 2 is carried out by the image pick-up means 53 and the control means that is not shown. That is, the image pick-up means 53 and the control means (not shown) carry out image processing such as pattern matching, etc. to align a street 23 formed in a predetermined direction of the semiconductor wafer 2 with the condenser 524 of the laser beam application means 52 for applying a laser beam along the street 23, thereby performing the alignment of a laser beam application position. The alignment of the laser beam application position is also carried out on streets 23 formed on the semiconductor wafer 2 in a direction perpendicular to the above predetermined direction. Since there is no feature point on the streets 23 in the above-mentioned alignment, the positional relationship between the feature points of semiconductor chips 22 (devices) as a key pattern and the streets 23 is in advance stored in the memory of the control means in the same manner as in the past and the streets 23 are detected indirectly by the pattern matching method.

After the street 23 formed on the semiconductor wafer 2 held on the chuck table 51 is detected and the alignment of the laser beam application position is carried out as described above, the chuck table 51 is moved to a laser beam application area where the condenser 524 of the laser beam application means 52 for applying a laser beam is located to bring the predetermined street 23 to a position right below the condenser 524, as shown in FIG. 7(a). At this point, as shown in FIG. 7 (a), the semiconductor wafer 2 is positioned such that one end (left end in FIG. 7(a)) of the street 23 is located right below the condenser 524. The chuck table 51, that is, the semiconductor wafer 2 is then moved in the direction indicated by the arrow X1 in FIG. 7(a) at a predetermined processing-feed rate while a pulse laser beam is applied from the condenser 524 of the laser beam application means 52. When the other end (right end in FIG. 7(b)) of the street 23 reaches a position right below the condenser 524 as shown in FIG. 7(b), the application of the pulse laser beam is suspended and the movement of the chuck table 51, that is, the semiconductor wafer 2 is stopped. In this groove forming step, the focusing point P of the pulse laser beam is set to a position near the front surface of the street 23.

Thereafter, the chuck table 51, that is, the semiconductor wafer 2 is moved about 30 to 40 μm in a direction (indexing-feed direction) perpendicular to the sheet. The chuck table 51, that is, the semiconductor wafer 2 is then moved in the direction indicated by the arrow X2 in FIG. 7 (b) at a predetermined processing-feed rate while a pulse laser beam is applied from the condenser 524 of the laser beam application means 52. When the one end of the street 23 reaches the position shown in FIG. 7(a), the application of the pulse laser beam is suspended and the movement of the chuck table 51, that is, the semiconductor wafer 2 is stopped.

By carrying out the above groove forming step, two grooves 24 and 24 deeper than the thickness of the laminate 21 are formed in the street 23 of the semiconductor wafer 2, as shown in FIG. 8. As a result, the laminate 21 is separated by the two grooves 24 and 24. The interval (B) between the outer sides of the two grooves 24 and 24 formed in the street 23 is set larger than the thickness, which will be described later, of the cutting blade,. The above groove forming step is carried out on all the streets 23 formed on the semiconductor wafer 2.

The above groove forming step is carried out under the following processing conditions, for example.

Light source of laser beam: YVO4 laser or YAG laser

Wavelength: 355 nm

Output: 2.0 W

Repetition frequency: 200 kHz

Pulse width: 300 ns

Focusing spot diameter: 10 μm

Processing-feed rate: 600 mm/sec

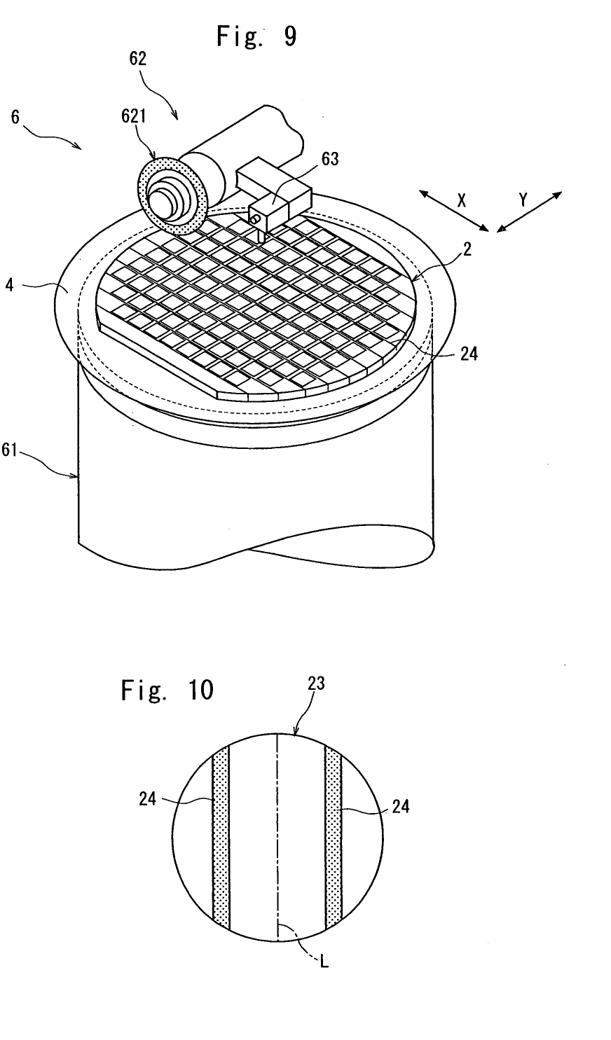

After the above groove forming step is carried out on all the streets 23 formed on the semiconductor wafer 2, next comes the step of cutting the semiconductor wafer 2 along the streets 23. The cutting machine 6 which is commonly used as a dicing machine as shown in FIG. 9 can be used in this cutting step. That is, the cutting machine 6 comprises a chuck table 61 having a suction-holding means, a cutting means 62 having a cutting blade 621, and an image pick-up means 63 for picking up an image of the workpiece held on the chuck table 61. The chuck table 61 is designed to be moved in the cutting-feed direction indicated by the arrow X in FIG. 9 by a cutting-feed mechanism (not shown) and in the indexing-feed direction indicated by the arrow Y by an indexing-feed mechanism that is not shown. Further, the chuck table 61 is turned by a rotation mechanism that is not shown. The above cutting blade 621 is desirably manufactured by, while forming a metal plating layer such as a nickel plating layer on the surface of a base in an electroplating liquid, dispersing fine abrasive grains such as diamond abrasive grains into this plating layer to form an edge made of a grinding layer, then plating the surface on the plating side of the above grinding layer with only a metal containing no fine abrasive grains, and thereafter, dressing the edge to uniformly expose the fine abrasive grains to both sides surfaces of the edge. That is, the cutting blade 621 thus formed has uniform cutting resistance on both sides of the cutting edge and does not slant at the time of cutting. The above image pick-up means 63 is arranged to align with the cutting blade 621 in the cutting-feed direction indicated by the arrow X. This image pick-up means 63 comprises an optical system and an image pick-up device (CCD) and transmits an image signal to a control means that is not shown.

A description will be subsequently given of the cutting step to be carried out by using the above cutting machine 6 with reference to FIGS. 9 to 13.

That is, the semiconductor wafer 2 which has been subjected to the above groove forming step is placed on the chuck table 61 of the cutting machine 6 in such a manner that the front surface 2a faces up and is held on the chuck table 61 by a suction means (not shown), as shown in FIG. 9. The chuck table 61 suction-holding the semiconductor wafer 2 is brought to a position right below the image pick-up means 63 by the cutting-feed mechanism that is not shown.

After the chuck table 61 is positioned right below the image pick-up means 63, an alignment step for detecting the area to be cut of the semiconductor wafer 2 is carried out by the image pick-up means 63 and the control means that is not shown. It is important that an image of the grooves 24 and 24 formed along the street 23 of the semiconductor wafer 2 in the groove forming step should be picked up by the image pick-up means 63 to carry out this alignment step. That is, the image pick-up means 63 picks up an image of a street 23 formed in the predetermined direction of the semiconductor wafer 2 and transmits its image signal to the control means that is not shown. At this point, since the grooves 24 and 24 are formed in the street 23 by the above groove forming step, the grooves 24 and 24 appear black in the image as shown in FIG. 10. The control means (not shown) adjusts the chuck table 61 holding the semiconductor wafer 2 such that the center between the grooves 24 and 24 is aligned with the hairline (L) of the image pick-up means 63 based on the image signal shown in FIG. 10, supplied from the image pick-up means 63 (alignment step). As a result, the cutting blade 621 that is arranged to align with the image pick-up means 63 in the cutting-feed direction indicated by the arrow X is positioned at the center position between the grooves 24 and 24. After the step of aligning the area to be cut is thus carried out on streets 23 formed in the predetermined direction of the semiconductor wafer 2, the step of aligning the area to be cut is also carried out similarly on streets 23 formed on the semiconductor wafer 2 in the direction perpendicular to the above predetermined direction.

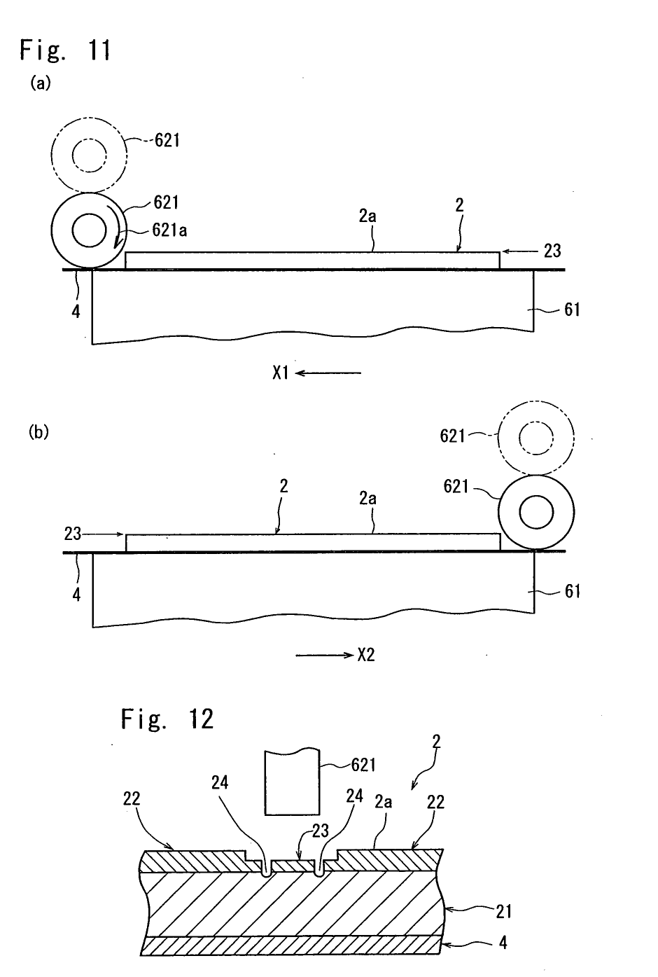

After the alignment of the area to be cut is carried out by detecting the street 23 formed on the semiconductor wafer 2 held on the chuck table 61 as described above, the chuck table 61 holding the semiconductor wafer 2 is moved to the cutting start position of the area to be cut. At this point, the semiconductor wafer 2 is positioned such that one end (left end in FIG. 11(a)) of the street 23 to be cut is situated on the right side by a predetermined distance from right below the cutting blade 621, as shown in FIG. 11(a). Since an image of the grooves 24 and 24 formed in the street 23 is directly picked up to detect the area to be cut in the above alignment step in the present invention, the center position between the two grooves 24 and 24 formed in the street 23 is aligned with the cutting blade 621 precisely, as shown in FIG. 12.

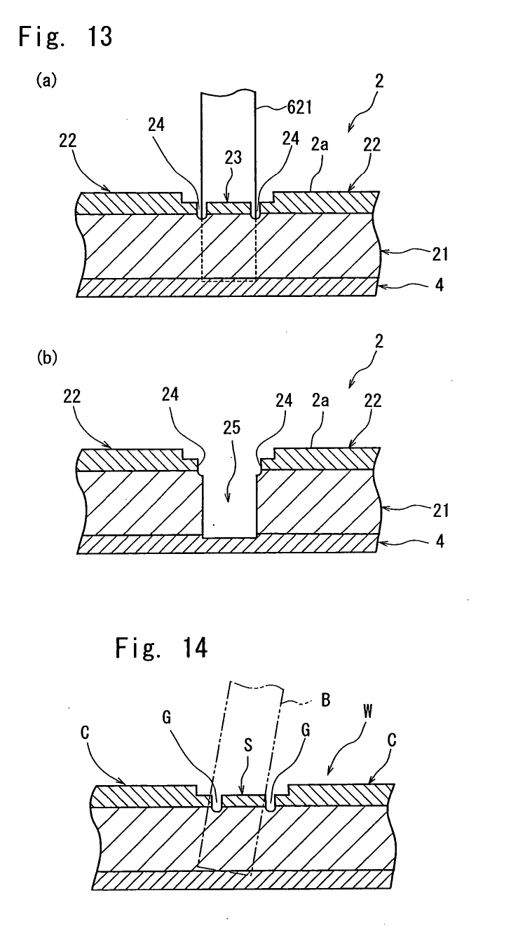

After the chuck table 61, that is, the semiconductor wafer 2 is brought to the cutting start position of the area to be cut as described above, the cutting blade 621 is moved down from its standby position shown by a two-dotted chain line in FIG. 11(a) to a predetermined cutting-feed position shown by a solid line in FIG. 11(a). This cutting-feed position is set to a position where the lower end of the cutting blade 621 reaches the protective tape 4 affixed to the back surface of the semiconductor wafer 2, as shown in FIG. 13(a).

Thereafter, the cutting blade 621 is rotated in the direction indicated by an arrow 621a in FIG. 11(a) at a predetermined revolution, and the chuck table 61, that is, the semiconductor wafer 2 is moved in the direction indicated by the arrow X1 in FIG. 11(a) at a predetermined cutting-feed rate. When the other end (right end in FIG. 11(b)) of the street 23 reaches a position on the left side by a predetermined distance from right below the cutting blade 621, as shown in FIG. 11(b), the movement of the chuck table 61, that is, the semiconductor wafer 2 is stopped. Thus, a cut groove 25 reaching the back surface is formed and cut between the outer sides of the grooves 24 and 24 formed in the street 23 of the semiconductor wafer 2 as shown in FIG. 13(b) by cutting-feeding the chuck table 61, that is, the semiconductor wafer 2 (cutting step). Since the cutting blade 621 is positioned at the center position between the two grooves 24 and 24 formed in the street 23 at this point, it does not slant and can cut the semiconductor wafer 2 along the two grooves 24 and 24.

Thereafter, the cutting blade 621 is moved up to its standby position shown by the two-dotted chain line in FIG. 11(b) and then, the chuck table 61, that is, the semiconductor wafer 2 is moved in the direction indicated by the arrow X2 in FIG. 11(b) to return to the position shown in FIG. 11(a). The chuck table 61, that is, the semiconductor wafer 2 is moved by a distance corresponding to the interval between streets 23 in the direction (indexing-feed step) perpendicular to the sheet so as to align the street 23 to be cut next with the cutting blade 621. After the street 23 to be cut next is located at a position corresponding to the cutting blade 621, the above-mentioned cutting step is carried out.

The above cutting step is carried out under the following processing conditions, for example.

Cutting blade: outer diameter of 52 mm, thickness of 40 μm

Revolution of cutting blade: 40,000 rpm

Cutting-feed rate: 50 mm/sec

The above cutting step is carried out on all the streets 23 formed on the semiconductor wafer 2. As a result, the semiconductor wafer 2 is cut along the streets 23 to be divided into individual semiconductor chips (devices).

What is claimed is:

1. A wafer dividing method for cutting a wafer having devices which are composed of a laminate laminated on the front surface of a substrate with a cutting blade along a plurality of streets for sectioning the devices, comprising the steps of:
a groove forming step for forming two grooves deeper than the thickness of the laminate at an interval larger than the thickness of the cutting blade by applying a laser beam along the streets formed on the wafer;
an alignment step for picking up an image of the two grooves formed in the streets of the wafer by the above groove forming step and positioning the cutting blade at the center position between the two grooves based on the image; and
a cutting step for moving the cutting blade and the wafer relative to each other while the cutting blade is rotated to cut the wafer along the streets having the two grooves formed therein, after the above alignment step.
